(19) United States
(12) Patent Application Publication
(10) Pub. No.: US 2024/0341160 A1
(43) Pub. Date: Oct. 10, 2024

(54) DISPLAY DEVICE AND METHOD FOR MANUFACTURING THE SAME

(71) Applicant: SAMSUNG DISPLAY CO., LTD., YONGIN-SI (KR)

(72) Inventors: Hyun Eok SHIN, Yongin-si (KR); Dong MIn LEE, Yongin-si (KR); Ju Hyun LEE, Yongin-si (KR)

(21) Appl. No.: 18/383,973

(22) Filed: Oct. 26, 2023

(30) Foreign Application Priority Data
Apr. 5, 2023 (KR) 10-2023-0044724

(51) Int. Cl. H10K 59/80; G06F 3/041; H10K 59/12; H10K 59/40

(52) U.S. Cl. CPC H10K 59/8792; G06F 3/0412; H10K 59/1201; H10K 59/40; G06F 3/04164; G06F 3/0446; G06F 2203/04107; G06F 2203/04112

(57) ABSTRACT

A display device includes: a display panel including a display area and a non-display area; a window disposed above the display panel and having a plurality of grooves that are formed on one surface of window facing the display panel; and viewing angle control members formed inside the plurality of grooves, wherein the viewing angle control members include light absorbing walls formed on sidewalls of the plurality of grooves and formed to become thinner as upper surfaces of the plurality of grooves are approached.

### CROSS-REFERENCE TO RELATED APPLICATION

This application claims priority under 35 U.S.C. § 119 to Korean Patent Application No. 10-2023-0044724 filed on Apr. 5, 2023 in the Korean Intellectual Property Office, the disclosure of which is incorporated by reference herein in its entirety.

### TECHNICAL FIELD

The present invention relates to a display device and a method for manufacturing the same.

### DISCUSSION OF THE RELATED ART

The desirability of display devices has increased with the development of multimedia. Accordingly, various types of display devices such as liquid crystal displays (LCD) and organic light emitting displays (OLEDs) have been under development.

Among the display devices, an organic light emitting display, generally, displays an image using organic light emitting elements that generate light by recombination of electrons and holes. The display device has a relatively fast response speed and a great luminance and viewing angle, and is driven with a relatively low power consumption.

The display device displays image information to a user. The display device is generally developed to have a wide viewing angle so that the user may view an image of the display device in various angular directions. However, when a display device or an electronic device including a display device has a wide viewing angle, it may adversely affect characteristics of the display device or the electronic device, and thus, a narrow viewing angle may be desirable.

For example, in a case of a navigation system of a vehicle, when a display device has a wide viewing angle, light is reflected on a windshield of the vehicle during night driving of the vehicle, which may adversely affect safe driving of a driver. For example, in a case of a computer or a mobile phone, even though a user does not want private information exposed, a wide viewing angle of a display device is contrary to a user's request.

### SUMMARY

According to an embodiment of the present invention, a display device includes: a display panel including a display area and a non-display area; a window disposed above the display panel and having a plurality of grooves that are formed on one surface of window facing the display panel; and viewing angle control members formed inside the plurality of grooves, wherein the viewing angle control members include light absorbing walls formed on sidewalls of the plurality of grooves and formed to become thinner as upper surfaces of the plurality of grooves are approached.

In an embodiment of the present invention, the light absorbing wall includes CuMgAlOx.

In an embodiment of the present invention, the viewing angle control members further includes fillers filled in inner portions of the grooves and are at least partially surrounded by the light absorbing walls, and the fillers are formed to become wider as the upper surfaces of the plurality of grooves are approached.

In an embodiment of the present invention, the filler is made of silica (SiO2) and a siloxane-based material.

In an embodiment of the present invention, a protective layer is disposed on one surface of the window and is disposed between the viewing angle control members.

In an embodiment of the present invention, the protective layer includes a transparent oxide film.

In an embodiment of the present invention, each of the light absorbing walls includes a first light absorbing wall and a second light absorbing wall, wherein the first light absorbing walls is formed on the sidewalls of the plurality of grooves, and the second light absorbing walls are formed on the upper surfaces of the plurality of grooves, and the second light absorbing walls are formed to be thinner than the first light absorbing walls.

In an embodiment of the present invention, the viewing angle control members includes fillers contacting the light absorbing walls.

In an embodiment of the present invention, the display device further includes a touch sensing layer disposed between the display panel and the window, wherein the viewing angle control members are disposed to face the touch sensing layer.

In an embodiment of the present invention, the touch sensing layer includes touch electrodes, and at least some of the viewing angle control members overlap the touch electrodes.

In an embodiment of the present invention, the display panel includes: a substrate; a light emitting element layer disposed on the substrate and including pixels including a pixel electrode, a light emitting layer, and a common electrode, and a pixel defining layer disposed on the pixel electrode; and a thin film encapsulation layer disposed on the light emitting element layer.

In an embodiment of the present invention, the viewing angle control members are disposed to face the thin film encapsulation layer.

According to an embodiment of the present invention, a method for manufacturing a display device includes: forming a plurality of grooves in a first surface of a window by using a hard mask and a photoresist mask; forming light absorbing walls on side surfaces of the plurality of grooves; filling inner portions of the grooves with fillers such that the fillers are at least partially surrounded by the light absorbing walls; and disposing the first surface of the window on a display panel, wherein the light absorbing walls are formed to become thinner as upper portions of the window are approached.

In an embodiment of the present invention, the method for manufacturing a display device further includes performing oxidation heat treatment on the light absorbing walls.

In an embodiment of the present invention, the hard mask includes a transparent oxide film.

In an embodiment of the present invention, in the forming of the light absorbing walls, CuMgAl is deposited on one surface of the window in which the grooves are formed, and is anisotropically etched.

In an embodiment of the present invention, the filler includes silica (SiO2) and a siloxane-based material.

In an embodiment of the present invention, the fillers are formed to become wider as the upper portions of the window are approached.

In an embodiment of the present invention, the display panel includes: a substrate; a light emitting element layer disposed on the substrate and including pixels including a pixel electrode, a light emitting layer, and a common electrode, and a pixel defining layer disposed on the pixel electrode; and a thin film encapsulation layer disposed on the light emitting element layer.

In an embodiment of the present invention, the method for manufacturing a display device further includes disposing a touch sensing layer on the display panel.

### BRIEF DESCRIPTION OF THE DRAWINGS

The above and other features of the present invention will become more apparent by describing in detail embodiments thereof with reference to the attached drawings, in which:

FIG. 1 is an exploded perspective view of a display device according to an embodiment of the present invention;

FIG. 2 is a plan view of the display device according to an embodiment of the present invention;

FIG. 3 is a cross-sectional view illustrating an example taken along line I-I′ of FIG. 2 of the present invention;

FIG. 4 is a view illustrating an example of a display unit of FIG. 3;

FIG. 5 is a view illustrating an example of a touch sensing layer of FIG. 3;

FIG. 6 is a plan view illustrating an example of sub-pixels of FIG. 4 and a first touch metal layer of FIG. 5;

FIG. 7 is a cross-sectional view illustrating an example taken along line II-II′ of FIG. 6;

FIG. 8 is an enlarged view of area B of FIG. 7;

FIG. 9 is a view for describing a viewing angle control member and traveling directions of light in FIG. 7;

FIGS. 10 and 11 are enlarged views of area B of FIG. 7 according to some embodiments of the present invention;

FIG. 12 is a graph for describing transmittance characteristics of silica (SiO₂) and a siloxane-based material with respect to a light wavelength;

FIG. 13 is a flowchart for describing a method for manufacturing a window according to an embodiment of the present invention;

FIGS. 14, 15, 16, 17 and 18 are cross-sectional views for describing the method for manufacturing a window according to an embodiment of the present invention;

FIG. 19 is a cross-sectional view illustrating an example taken along line I-I′ of FIG. 2 according to an embodiment of the present invention;

FIG. 20 is a cross-sectional view illustrating an example taken along line II-II′ of FIG. 6 according to an embodiment of the present invention; and

FIG. 21 is a view illustrating an example to which a display device according to an embodiment of the present invention is applied.

### DETAILED DESCRIPTION OF THE EMBODIMENTS

The embodiments of the present invention will now be described more fully hereinafter with reference to the accompanying drawings. The embodiments of the present invention may, however, be provided in different forms and should not be construed as limiting. The same reference numbers indicate the same components throughout the specification and drawings. In the accompanying figures, various thicknesses, lengths, and angles are shown and while the arrangement shown does indeed represent an embodiment of the present disclosure, it is to be understood that modifications of the various thicknesses, lengths, and angles may be possible within the spirit and scope of the present disclosure and the present disclosure is not necessarily limited to the particular thicknesses, lengths, and angles shown.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, unless indicated otherwise, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include, for example, layer, stack, face or facing, extending over, covering, or partly covering or any other suitable term as would be appreciated and understood by those of ordinary skill in the art. The expression “not overlap” may include, for example, meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions, and thus, the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with no intervening elements present or one or more intervening elements interposed therebetween.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings of the present invention.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Hereinafter, embodiments of the present invention will be described in detail with reference to the accompanying drawings.

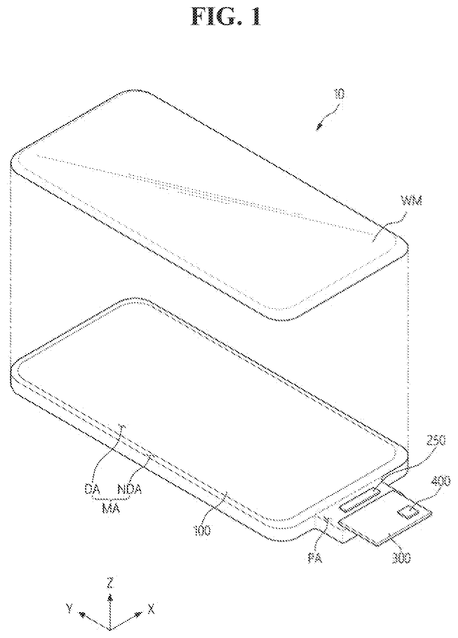

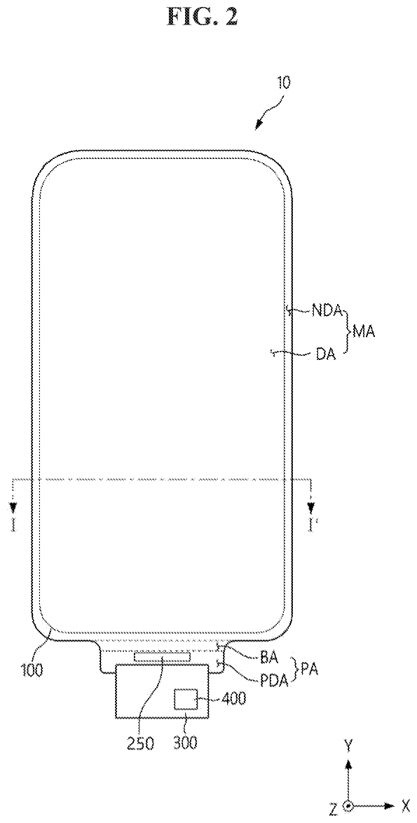

FIG. 1 is an exploded perspective view of a display device according to an embodiment of the present invention. FIG. 2 is a plan view of the display device according to an embodiment of the present invention.

The terms “above”, “top”, and “upper surface” as used herein may refer to an upward direction (e.g., a Z-axis direction) with respect to a display panel 100. The terms “below”, “bottom”, and “lower surface” as used herein may refer to a downward direction (e.g., a direction opposite to the Z-axis direction) with respect to the display panel 100. In addition, “left”, “right”, “upper”, and “lower” may refer to directions when the display panel 100 is viewed in plan view. For example, on a plane such as a surface, “left” refers to a direction opposite to an X-axis direction, “right” refers to the X-axis direction, “upper” refers to a Y-axis direction, and “lower” refers to a direction opposite to the Y-axis direction.

Referring to FIGS. 1 and 2, a display device 10 is a device that displays a moving image or a still image, and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). The display device 10 may be any one of, for example, an organic light emitting display, a liquid crystal display, a plasma display panel, a field emission display, an electrophoretic display, an electro-wetting display, a quantum dot light emitting display, and a micro light emitting diode (LED) display. Hereinafter, it will be mainly described that the display device 10 is the organic light emitting display, but the present invention is not limited thereto.

The display device 10 according to an embodiment of the present invention includes a window WM, a display panel 100, a display driving circuit 250, a circuit board 300, and a touch driving circuit 400.

The window WM covers the display panel 100 to protect the display panel 100 from external impact and contaminants. In the present embodiment, the window WM may be a glass substrate or a plastic substrate having a light transmission property.

The display panel 100 may include a main area MA and a protrusion area PA protruding from one side of the main area MA.

The main area MA may be formed in a rectangular shape, in plan view, having short sides in a first direction (X-axis direction) and long sides in a second direction (Y-axis direction) crossing the first direction (X-axis direction). A corner where the short side in the first direction (X-axis direction) and the long side in the second direction (Y-axis direction) meet may be rounded with a predetermined radius of curvature or right-angled. The shape of the display device 10 in plan view is not limited to the rectangular shape, and may be other polygonal shapes, a circular shape, or an elliptical shape. The main area MA may be formed to be flat, but is not limited thereto, and may include curved surface portions formed at left and right ends thereof. In this case, the curved surface portions may have a substantially constant curvature or a variable curvature.

The main area MA may include a display area DA in which pixels are formed to display an image, and a non-display area NDA, which is a peripheral area of the display area DA.

Scan lines, data lines, and power lines connected to the pixels as well as the pixels may be disposed in the display area DA. When the main area MA includes the curved surface portions, the display area DA may be disposed on the curved surface portions. In this case, the image of the display panel 100 may be viewed even on the curved portions.

The non-display area NDA may be an area from an outer side of the display area DA to an edge of the display panel 100. A scan driver for applying scan signals to the scan lines may be disposed in the non-display area NDA, and link lines connecting the data lines and the display driving circuit 250 to each other may be disposed in the non-display area NDA.

The protrusion area PA may protrude from one side of the main area MA. For example, the protrusion area PA may protrude from a lower side of the main area MA as illustrated in FIG. 2. A length of the protrusion area PA in the first direction (X-axis direction) may be smaller than a length of the main area MA in the first direction (X-axis direction).

The protrusion area PA may include a bending area BA and a pad area PDA. In this case, the pad area PDA may be disposed on one side of the bending area BA, and the main area MA may be disposed on the other side of the bending area BA. For example, the pad area PDA may be disposed on the lower side of the bending area BA, and the main area MA may be disposed on the upper side of the bending area BA.

The display panel 100 may be flexibly formed to be curved, bent, folded, or rolled. Therefore, the display panel 100 may be bent in a thickness direction (Z-axis direction) in the bending area BA. In this case, one surface of the pad area PDA of the display panel 100 faces upward before the display panel 100 is bent, but one surface of the pad area PDA of the display panel 100 faces downward after the display panel 100 is bent. For this reason, the pad area PDA is disposed below the main area MA, and may thus overlap the main area MA.

Pads electrically connected to the display driving circuit 250 and the circuit board 300 to each other may be disposed in the pad area PDA of the display panel 100.

The display driving circuit 250 outputs signals and voltages for driving the display panel 100. For example, the display driving circuit 250 may supply data voltages to the data lines. In addition, the display driving circuit 250 may supply source voltages to the power lines, and may supply scan control signals to the scan driver. The display driving circuit 250 may be formed as an integrated circuit (IC) and mounted on the display panel 100 in the pad area PDA in a chip on glass (COG) manner, a chip on plastic (COP) manner, or an ultrasonic bonding manner, but the present invention is not limited thereto. For example, the display driving circuit 250 may be mounted on the circuit board 300.

The pads may include display pads, which are electrically connected to the display driving circuit 250, and touch pads, which are electrically connected to touch lines.

The circuit board 300 may be attached onto the pads using an anisotropic conductive film (ACF). For this reason, lead lines of the circuit board 300 may be electrically connected to the pads. The circuit board 300 may be, for example, a flexible printed circuit board, a printed circuit board, or a flexible film such as a chip on film.

The touch driving circuit 400 may be connected to touch electrodes of a touch sensing layer TSL of the display panel 100. The touch driving circuit 400 applies driving signals to the touch electrodes of the touch sensing layer TSL and measures capacitance values of the touch electrodes. The driving signal may be a signal having a plurality of driving pulses. The touch driving circuit 400 may decide whether or not a touch has been input according to the capacitance values and may calculate touch coordinates where the touch has been input.

The touch driving circuit 400 may be disposed on the circuit board 300. The touch driving circuit 400 may be formed as an integrated circuit (IC) and mounted on the circuit board 300.

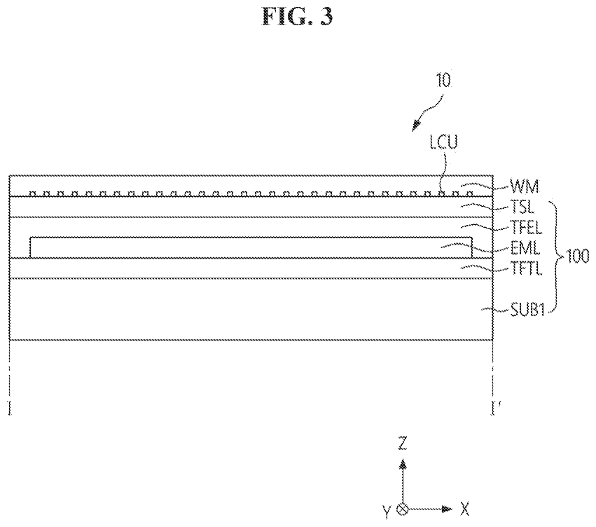

FIG. 3 is a cross-sectional view illustrating an example taken along line I-I′ of FIG. 2.

Referring to FIG. 3, the display panel 100 may include a substrate SUB1, a thin film transistor layer TFTL disposed on the substrate SUB1, a light emitting element layer EML, a thin film encapsulation layer TFEL, and a touch sensing layer TSL. A window (WM) is disposed on the display panel 100.

The substrate SUB1 may be made of an insulating material such as glass, quartz, or a polymer resin. Examples of the polymer resin may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. In addition, the substrate SUB1 may include a metal material.

The substrate SUB1 may be a rigid substrate or be a flexible substrate that may be bent, folded, and rolled. For example, when the substrate SUB1 is the flexible substrate, the substrate SUB1 may be made of polyimide (PI), but present invention is not limited thereto.

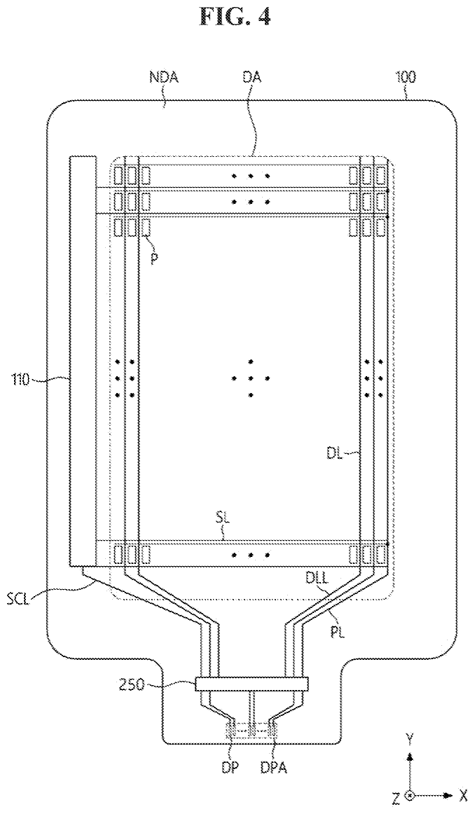

The thin film transistor layer TFTL may be disposed on the substrate SUB1. The scan lines, the data lines, the power lines, scan control lines, routing lines connecting the pads and the data lines to each other, and the like, as well as thin film transistors of each of the pixels may be formed in the thin film transistor layer TFTL. Each of the thin film transistors may include a gate electrode, a semiconductor layer, a source electrode, and a drain electrode. When a scan driver 110 is formed in the non-display area NDA of the display panel 100 as illustrated in FIG. 4, the scan driver 110 may include thin film transistors.

The thin film transistor layer TFTL may be disposed in the display area DA and the non-display area NDA. For example, the thin film transistors of each of the pixels, the scan lines, the data lines, and the power lines of the thin film transistor layer TFTL may be disposed in the display area DA. The scan control lines and the link lines of the thin film transistor layer TFTL may be disposed in the non-display area NDA.

The light emitting element layer EML may be disposed on the thin film transistor layer TFTL. The light emitting element layer EML may include pixels each including a first electrode, a light emitting layer, and a second electrode, and a pixel defining layer defining the pixels. The light emitting layer may be an organic light emitting layer including an organic material. In this case, the light emitting layer may include a hole transporting layer, an organic light emitting layer, and an electron transporting layer. When a predetermined voltage is applied to the first electrode through the thin film transistor of the thin film transistor layer TFTL and a cathode voltage is applied to the second electrode, holes and electrons move to the organic light emitting layer through the hole transporting layer and the electron transporting layer, respectively, and are combined with each other in the organic light emitting layer to emit light. The pixels of the light emitting element layer EML may be disposed in the display area DA.

The thin film encapsulation layer TFEL may be disposed on the light emitting element layer EML. The thin film encapsulation layer TFEL serves to prevent oxygen or moisture from penetrating into the light emitting element layer EML. The thin film encapsulation layer TFEL may include at least one inorganic film. The inorganic film may be, for example, a silicon nitride layer, a silicon oxynitride layer, a silicon oxide layer, a titanium oxide layer, or an aluminum oxide layer, but is not limited thereto. In addition, the thin film encapsulation layer TFEL serves to protect the light emitting element layer EML from foreign substances such as dust. To this end, the thin film encapsulation layer TFEL may include at least one organic film. The organic film may be made of, for example, an acrylic resin, an epoxy resin, a phenolic resin, a polyamide resin, or a polyimide resin, but the present inventive concept is not limited thereto.

The thin film encapsulation layer TFEL may be disposed in both the display area DA and the non-display area NDA. For example, the thin film encapsulation layer TFEL may be disposed to cover the light emitting element layer EML of the display area DA and the non-display area NDA and cover the thin film transistor layer TFTL of the non-display area NDA.

The touch sensing layer TSL may be disposed on the thin film encapsulation layer TFEL. Since the touch sensing layer TSL is disposed on the thin film encapsulation layer TFEL, a thickness of the display device 10 may be reduced as compared with a case where a separate touch panel including the touch sensing layer TSL is attached onto the thin film encapsulation layer TFEL. For example, the touch sensing layer TSL may be directly disposed on the thin film encapsulation layer TFEL.

The touch sensing layer TSL may include touch electrodes, which are for sensing a user's touch in a capacitance manner, and touch lines, which connect the pads and the touch electrodes to each other. For example, the touch sensing layer TSL may sense the user's touch in a self-capacitance manner or a mutual capacitance manner.

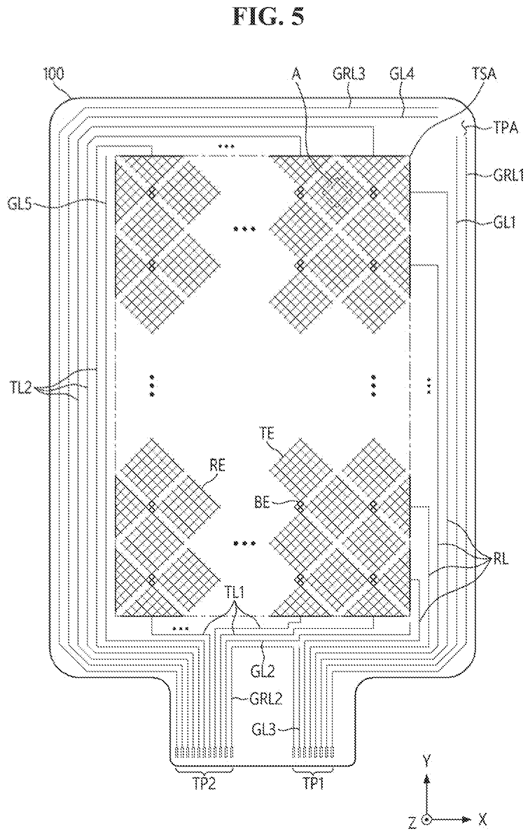

The touch electrodes of the touch sensing layer TSL may be disposed in a touch sensor area TSA overlapping the display area DA as illustrated in FIG. 5. The touch lines of the touch sensing layer TSL may be disposed in a touch peripheral area TPA overlapping the non-display area NDA as illustrated in FIG. 5.

The window WM may be disposed on the touch sensing layer TSL.

The window WM may provide a front surface of the display device 10. The window WM may be made of, for example, glass, sapphire, plastic, or the like.

In an embodiment of the present invention, a plurality of grooves arranged in the first direction (X-axis direction) and extending in the second direction (Y-axis direction) that is substantially perpendicular to the first direction (X-axis direction) may be defined in a lower surface of the window WM. However, the grooves are not limited thereto, and may be arranged in the second direction (Y-axis direction) and extend in the first direction (X-axis direction). In addition, a viewing angle control member LCU may be disposed in each of the plurality of grooves. The viewing angle control member (LCU) is made of a material having a light absorbing function. The material having a light absorbing function may be, for example, CuMgAlOₓ having excellent adhesion and light absorbing properties, but the present invention is not limited thereto.

The grooves formed in the lower surface of the window WM may be disposed to overlap the display area DA. Accordingly, the viewing angle control members LCU may be disposed to overlap the display area DA.

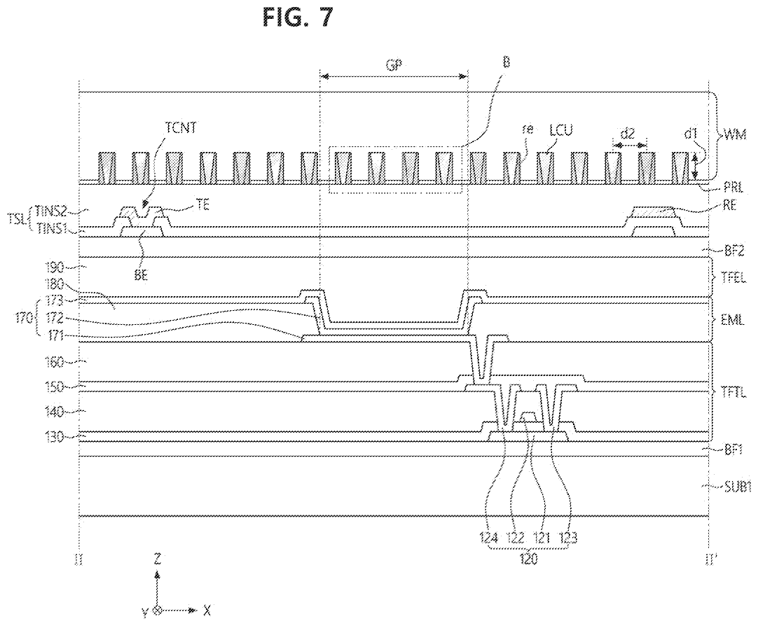

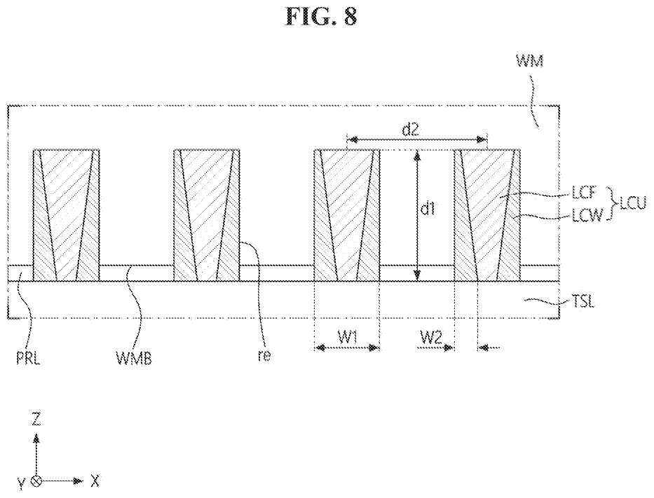

A traveling direction of light provided from the display panel 100 may be controlled by the viewing angle control members LCU that is disposed in the grooves that are formed in the lower surface of the window WM. This will be described with reference to FIGS. 7 and 8.

The window WM and the display panel 100 may be attached to each other by a transparent adhesive member such as an optically clear adhesive (OCA) film.

FIG. 4 is an illustrative view illustrating an example of a display unit of FIG. 3.

In FIG. 4, for convenience of explanation, tpixels P, scan lines SL, data lines DL, and a power line PL of the display area DA, scan control lines SCL, the scan driver 110, the display driving circuit 250, and display pads DDP have been illustrated.

Referring to FIG. 4, the scan lines SL, the data lines DL, the power line PL, and the pixels P are disposed in the display area DA. The scan lines SL may be formed in parallel with each other in the first direction (X-axis direction), and the data lines DL may be formed in parallel with each other in the second direction (Y-axis direction) crossing the first direction (X-axis direction). The power line PL may include at least one line, which is formed in parallel with the data lines DL in a second direction (Y-axis direction), and a plurality of lines branched from at least one line in the first direction (X-axis direction).

Each of the pixels P may be connected to at least one of the scan lines SL, any one of the data lines DL, and the power line PL. Each of the pixels P may include thin film transistors including a driving transistor and at least one switching transistor, an organic light emitting diode, and a capacitor. Each of the pixels P may receive a data voltage of the data line DL when a scan signal is applied from the scan line SL, and may supply a driving current to the organic light emitting diode according to the data voltage that is applied to a gate electrode to emit light.

The scan driver 110 is connected to the display driving circuit 250 through at least scan control line SCL. Therefore, the scan driver 110 may receive scan control signals of the display driving circuit 250. The scan driver 110 generates scan signals according to the scan control signals and supplies the scan signals to the scan lines SL.

It has been illustrated in FIG. 5 that the scan driver 110 is formed in the non-display area NDA and is positioned on the outer left side of the display area DA, but the present invention is not limited thereto. For example, the scan drivers 110 may be disposed in the non-display areas NDA and positioned on the outer left side and the outer right side of the display area DA.

The display driving circuit 250 is connected to the display pads DP to receive digital video data and timing signals. The display driving circuit 250 converts the digital video data into analog positive/negative data voltages and supplies the analog positive/negative data voltages to the data lines DL through link lines DLL. In addition, the display driving circuit 250 generates and supplies the scan control signals for controlling the scan driver 110 through the scan control lines SCL. Pixels P to which the data voltages are to be supplied are selected by the scan signals of the scan driver 110, and the data voltages are supplied to the selected pixels P. The display driving circuit 250 may be formed as an integrated circuit (IC) and attached onto the substrate SUB1 in a chip on glass (COG) manner, a chip on plastic (COP) manner, or an ultrasonic bonding manner.

FIG. 5 is an illustrative view illustrating an example of a touch sensing layer of FIG. 3 in detail.

In FIG. 5, for convenience of explanation, touch electrodes TE and RE, touch lines TL and RL, and touch pads TP have been illustrated.

Referring to FIG. 5, the touch sensing layer TSL includes a touch sensor area TSA for sensing a user's touch and a touch peripheral area TPA disposed around the touch sensor area TSA. The touch sensor area TSA may overlap the display area DA, and the touch peripheral area TPA may overlap the non-display area NDA.

The touch electrodes TE and RE may be disposed in the touch sensor area TSA. The touch electrodes TE and RE may include sensing electrodes RE and driving electrodes TE. The sensing electrodes RE may be electrically connected to each other in the first direction (X-axis direction), and the driving electrodes TE may be electrically connected to each other in the second direction (Y-axis direction) that crosses the first direction (X-axis direction). In addition, it has been illustrated in FIG. 5 that the sensing electrodes RE and the driving electrodes TE are formed in a diamond shape in plan view, but the present invention is not limited thereto.

To prevent the sensing electrodes RE and the driving electrodes TE from being short-circuited to each other at where the sensing electrodes RE cross the driving electrodes TE, the driving electrodes TE that are adjacent to each other in the second direction (Y-axis direction) may be connected to each other through a connection electrode BE. In this case, the driving electrodes TE and the sensing electrodes RE may be disposed at one layer, and the connection electrode BE may be disposed at a layer different from the layer at which the driving electrodes TE and the sensing electrodes RE are disposed. In addition, the sensing electrodes RE electrically connected to each other in the first direction (X-axis direction) and the driving electrodes TE electrically connected to each other in the second direction (Y-axis direction) are electrically insulated from each other.

The touch lines TL and RL may be disposed in the touch peripheral area TPA. The touch lines TL and RL may include sensing lines RL, first driving lines TL1, and second driving lines TL2. The sensing lines RL may be connected to the sensing electrodes RE, and the first driving lines TL1 and the second driving lines TL2 may be connected to driving electrodes TE.

The sensing electrodes RE disposed on the right side of the touch sensor area TSA may be connected to the sensing lines RL. For example, a sensing electrode RE, which is disposed at a right end among the sensing electrodes RE electrically connected to each other in the first direction (x-axis direction), may be connected to the sensing line RL. The sensing lines RL may be connected to first touch pads TPL. For this reason, the touch driving circuit 400 may be electrically connected to the sensing electrodes RE.

The driving electrodes TE that are disposed on the lower side of the touch sensor area TSA may be connected to the first driving lines TL1, and the driving electrodes TE that are disposed on the upper side of the touch sensor area TSA may be connected to the second driving lines TL2. For example, a driving electrode TE, which is disposed at a lower end among the driving electrodes TE electrically connected to each other in the second direction (Y-axis direction), may be connected to the first driving line TL1, and a driving electrode TE, which is disposed at an upper end among the driving electrodes TE electrically connected to each other in the second direction (Y-axis direction), may be connected to the second driving line TL2. The second driving lines TL2 may be connected to the driving electrodes TE that are on the upper side of the touch sensor area TSA via the outer left side of the touch sensor area TSA. The first driving lines TL1 and the second driving lines TL2 may be connected to second touch pads TP2. For this reason, the touch driving circuit 400 may be electrically connected to the driving electrodes TE.

The touch electrodes TE and RE may be driven in a mutual capacitance manner or a self-capacitance manner. First, when the touch electrodes TE and RE are driven in the mutual capacitance manner, driving signals are supplied to the driving electrodes TE through the first driving lines TL1 and the second driving lines TL2 to charge mutual capacitances formed in crossing areas that are formed by crossings of the sensing electrodes RE with the driving electrodes TE. Then, charge variations of the sensing electrodes RE are measured through the sensing lines RL, and it is decided whether a touch has been input according to the charge variations of the sensing electrodes RE. The driving signal may be a signal having a plurality of driving pulses.

Second, when the touch electrodes TE and RE are driven in the self-capacitance manner, driving signals are supplied to both the driving electrodes TE and the sensing electrodes RE through the first driving lines TL1, the second driving lines TL2, and the sensing lines RL to charge self-capacitances of the driving electrodes TE and the sensing electrodes RE. Then, charge variations of the self-capacitances of the driving electrodes TE and the sensing electrodes RE are measured through the first driving lines TL1, the second driving lines TL2, and the sensing lines RL, and it is decided whether a touch has been input according to the charge variations of the self-capacitances.

The driving electrodes TE, the sensing electrodes RE, and the connection electrodes BE may be formed as mesh-type electrodes as illustrated in FIG. 5. When the touch sensing layer TSL including the driving electrodes TE and the sensing electrodes RE is formed on the thin film encapsulation layer TFEL as illustrated in FIG. 3, distances between the second electrodes of the light emitting element layer EML and the driving electrodes TE or the sensing electrodes RE of the touch sensing layer TSL is relatively small, and thus, very great parasitic capacitances may be formed between the second electrodes of the light emitting element layer EML and the driving electrodes TE or sensing electrodes RE of the touch sensing layer TSL. Therefore, to reduce the parasitic capacitances, it is desirable that the driving electrodes TE and the sensing electrodes RE are formed as mesh-type electrodes as illustrated in FIG. 5 rather than being formed as non-pattern electrodes of a conductive layer made of transparent oxide such as indium tin oxide (ITO) or indium zinc oxide (IZO).

A first guard line GL1 may be disposed outside a sensing line RL disposed on the outermost side among the sensing lines RL. In addition, a first ground line GRL1 may be disposed outside the first guard line GL1. For example, the first guard line GL1 may be disposed on the right side of a sensing line RL disposed at a right end among the sensing lines RL, and the first ground line GRL1 may be disposed on the right side of the first guard line GL1.

A second guard line GL2 may be disposed between a sensing line RL, which is disposed on the innermost side among the sensing lines RL, and a first driving line TL1, that is disposed at a right end among the first driving lines TL1. In addition, the second guard line GL2 may be disposed between the first driving line TL1, that is disposed at the right end among the first driving lines TL1, and a second ground line GRL2. Furthermore, a third guard line GL3 may be disposed between the sensing line RL, which is disposed on the innermost side among the sensing lines RL, and the second ground line GRL2. The second ground line GRL2 may be connected to a first touch pad that is disposed on the leftmost side among the first touch pads TP1 and a second touch pad that is disposed on the rightmost side among the second touch pads TP2.

A fourth guard line GL4 may be disposed outside a second driving line TL2 that is disposed on the outermost side among the second driving lines TL2. In addition, a third ground line GRL3 may be disposed outside the fourth guard line GL4. For example, the fourth guard line GL4 may be disposed on the left side and the upper side of a second driving line TL2 that is disposed at the left side and the upper side among the second driving lines TL2, and the third ground line GRL3 may be disposed on the left side and the upper side of the fourth guard line GL4.

A fifth guard line GL5 may be disposed at a right side of a second driving line TL2 that is disposed on the right outermost side among the second driving lines TL2. For example, the fifth guard line GL5 may be disposed between a second driving line TL2, which is disposed at a right end among the second driving lines TL2, and the touch sensor area TSA. For example, the fifth guard line GL5 may be disposed between a second driving line TL2, which is disposed at a right end among the second driving lines TL2, and the touch electrodes TE and RE. For example, the fifth guard line GL5 may be disposed between a second driving line TL2, which is disposed at a right end among the second driving lines TL2, and the touch sensor area TSA.

According to an embodiment of the present inventive concept, with reference to FIG. 5, the first ground line GRL1, the second ground line GRL2, and the third ground line GRL3 are disposed adjacent to the upper side, the left side, the right side, and bottom side of the display panel 100. For example, the first ground line GRL1 may be disposed adjacent to the right side of the display panel 100, and the second ground line GRL2 may be disposed adjacent to the lower side of the display panel 100. For example, the third ground line GRL3 may be disposed adjacent to the upper side and the left side of the display panel 100. In addition, a ground voltage is applied to the first ground line GRL1, the second ground line GRL2, and the third ground line GRL3. For this reason, when static electricity is applied from the outside, the static electricity may be discharged to the first ground line GRL1, the second ground line GRL2, and the third ground line GRL3.

In addition, according to an embodiment of the present invention, with reference to FIG. 5, the first guard line GL1 is disposed between the sensing line RL, which disposed on the outermost end of the arrangement of the sensing lines RL, and the first ground line GRL1, and may thus serve to minimize an influence of the sensing line RL, which is disposed on the outermost end of the arrangement of the sensing lines RL, by a voltage change of the first ground line GRL1. The second guard line GL2 is disposed between the sensing line RL, which is disposed at the innermost end of the arrangement of the sensing lines RL, and the first driving line TL1, which is disposed at the outermost end of the arrangement of the first driving lines TL1. For this reason, the second guard line GL2 may serve to minimize an influence of the sensing line RL, which is disposed at the innermost end of the arrangement of the sensing lines RL, and the first driving line TL1, which is disposed at the outermost end of the arrangement of the first driving lines TL1, by a voltage change. The third guard line GL3 is disposed between the sensing line RL, which is disposed on the innermost end of the arrangement of the sensing lines RL, and the second ground line GRL2, and may thus, serve to minimize an influence of the sensing line RL, which is disposed on the innermost end of the arrangement of the sensing lines RL, by a voltage change of the second ground line GRL2. The fourth guard line GL4 is disposed between the second driving line TL2, which is disposed on the outermost end of the arrangement of second driving lines TL2, and the third ground line GRL3, and may thus serve to minimize an influence of the second driving line TL2 by a voltage change of the third ground line GRL3. The fifth guard line GL5 is disposed between the second driving line TL2, which is disposed on the innermost end of the arrangement of the second driving lines TL2, and the touch electrodes TE and RE, and may thus serve to minimize mutual influences between the second driving line TL2, which is disposed on the innermost end of the arraignment of the second driving lines TL2, and the touch electrodes TE and RE.

When the touch electrodes TE and RE are driven in the mutual capacitance manner, a ground voltage may be applied to the first guard line GL1, the second guard line GL2, the third guard line GL3, the fourth guard line GL4, and the fifth guard line GL5. In addition, when the touch electrodes TE and RE are driven in the self-capacitance manner, the same driving signals as driving signals applied to the first driving lines TL1, the second driving lines TL2, and the sensing lines RL may be applied to the first guard line GL1, the second guard line GL2, the third guard line GL3, the fourth guard line GL4, and the fifth guard line GL5.

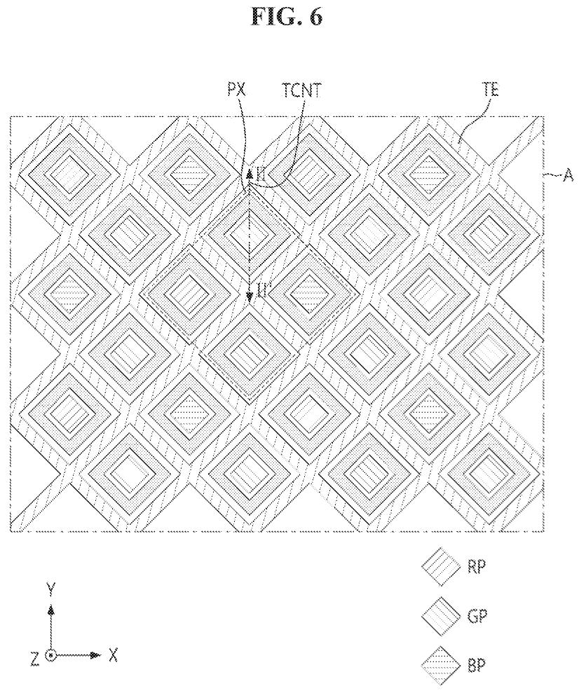

FIG. 6 is a plan view illustrating an example of sub-pixels of FIG. 4 and a first touch metal layer of FIG. 5.

Referring to FIG. 6, sub-pixels may include first sub-pixels RP, second sub-pixels GP, and third sub-pixels BP. Each of the first sub-pixels RP may display a first color, and each of the second sub-pixels GP may display a second color. Each of the third sub-pixels BP may display a third color. For example, the first color may be red, the second color may be green, and the third color may be blue, but the present invention is not limited thereto.

The display panel 100 may express a white gradation in units of pixels P. One first sub-pixel RP, two second sub-pixels GP, and one third sub-pixel BP may form one pixel P. In addition, the first sub-pixel RP, the second sub-pixels GP, and the third sub-pixel BP, which form one pixel P, may be disposed in a rhombic shape as illustrated in FIG. 6.

In the display panel 100, the number of first sub-pixels RP and the number of third sub-pixels BP may be the same as each other. In the display panel 100, the number of second sub-pixels GP may be twice the number of first sub-pixels RP and twice the number of third sub-pixels BP. In addition, in the display panel 100, the number of second sub-pixels GP may be the same as the sum of the number of first sub-pixels RP and the number of third sub-pixels BP.

It has been illustrated in FIG. 6 that the first sub-pixels RP, the second sub-pixels GP, and the third sub-pixels BP are formed in the rhombic shape in plan view, but the present invention is not limited thereto. For example, the first sub-pixels RP, the second sub-pixels GP, and the third sub-pixels BP may be formed in a rectangular shape or a square shape in plan view or may be formed in other polygonal shapes, a circular shape, or an elliptical shape in plan view. In addition, a shape of the first sub-pixel RP, a shape of the second sub-pixel GP, and a shape of the third sub-pixel BP may be different from each other.

It has been illustrated in FIG. 6 that a size of the first sub-pixel RP, a size of the second sub-pixel GP, and a size of the third sub-pixel BP in plan view are the same as each other, but the present invention is not limited thereto. For example, a size of the first sub-pixel RP, a size of the second sub-pixel GP, and a size of the third sub-pixel BP in plan view may be different from each other. For example, in plan view, the size of the first sub-pixel RP may be greater than the size of the second sub-pixel GP, and the size of the third sub-pixel BP may be greater than the size of the second sub-pixel GP. In addition, in plan view, the size of the first sub-pixel RP may be substantially the same as or smaller than the size of the third sub-pixel BP.

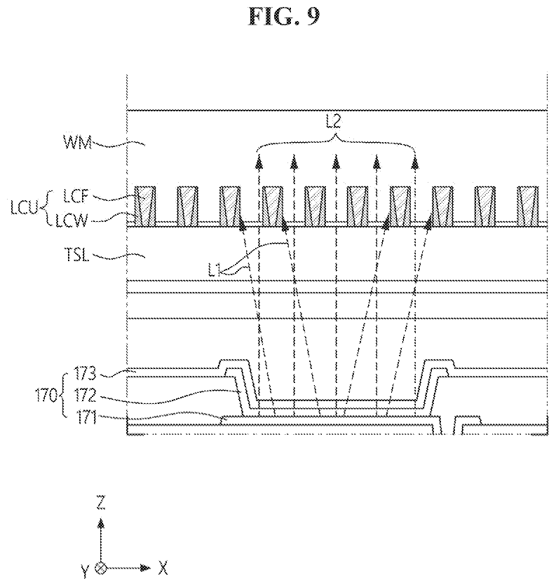

FIG. 7 is a cross-sectional view illustrating an example taken along line II-II′ of FIG. 6, and FIG. 8 is an enlarged view of area B of FIG. 7. In addition, FIG. 9 is a view for describing a viewing angle control member and traveling directions of light in FIG. 7.

Referring to FIGS. 7 and 8, the thin film transistor layer TFTL is formed on the substrate SUB1. The thin film transistor layer TFTL includes thin film transistors 120, a gate insulating layer 130, an interlayer insulating layer 140, a passivation layer 150, and a planarization layer 160.

A first buffer layer BF1 may be formed on one surface of the substrate SUB1. The first buffer layer BF1 may be formed on one surface of the substrate SUB1 to protect the thin film transistors 120 and an organic light emitting layer 172 of the light emitting element layer EML from moisture permeating through the substrate SUB1 vulnerable to moisture permeation. The first buffer layer BF1 may include a plurality of inorganic films that are alternately stacked on each other. For example, the first buffer layer BF1 may be formed as multiple films in which one or more inorganic films of a silicon nitride layer, a silicon oxynitride layer, a silicon oxide layer, a titanium oxide layer, and an aluminum oxide layer are alternately stacked on each other. The first buffer layer BF1 may be omitted.

The thin film transistors 120 are formed on the first buffer layer BF1. The thin film transistor 120 includes an active layer 121, a gate electrode 122, a source electrode 123, and a drain electrode 124. It has been illustrated in FIG. 7 that the thin film transistor 120 is formed in a top gate type in which the gate electrode 122 is positioned above the active layer 121, but it should be noted that the present invention is not limited thereto. For example, the thin film transistors 120 may be formed in a bottom gate type in which the gate electrode 122 is positioned below the active layer 121 or a double gate type in which the gate electrodes 122 are positioned both above and below the active layer 121.

The active layer 121 is formed on the first buffer layer BF1. The active layer 121 may include, for example, polycrystalline silicon, single crystal silicon, low-temperature polycrystalline silicon, amorphous silicon, or an oxide semiconductor. For example, the oxide semiconductor may include a binary compound (ABₓ), a ternary compound (ABₓC_{y}), or a quaternary compound (ABₓC_{y}D_{z}) including indium, zinc, gallium, tin, titanium, aluminum, hafnium (Hf), zirconium (Zr), magnesium (Mg), and the like. For example, the active layer 121 may include ITZO (oxide containing indium, tin, and titanium) or IGZO (oxide containing indium, gallium, and tin). A light blocking layer for blocking external light incident on the active layer 121 may be formed between the buffer layer BF1 and the active layer 121.

The gate insulating layer 130 may be formed on the active layer 121. The gate insulating layer 130 may be formed as an inorganic film such as a silicon nitride layer, a silicon oxynitride layer, a silicon oxide layer, a titanium oxide layer, or an aluminum oxide layer.

The gate electrode 122 and a gate line may be formed on the gate insulating layer 130. The gate electrode 122 and the gate line may be formed as a single layer or multiple layers including any one of, for example, molybdenum (Mo), aluminum (Al), chromium (Cr), gold (Au), titanium (Ti), nickel (Ni), neodymium (Nd), and copper (Cu), or alloys thereof.

The interlayer insulating layer 140 may be formed on the gate electrode 122 and the gate line. The interlayer insulating film 140 may be formed as an inorganic film such as a silicon nitride layer, a silicon oxynitride layer, a silicon oxide layer, a titanium oxide layer, or an aluminum oxide layer.

The source electrode 123 and the drain electrode 124 may be formed on the interlayer insulating layer 140. Each of the source electrode 123 and the drain electrode 124 may be connected to the active layer 121 through each of contact holes penetrating through the gate insulating layer 130 and the interlayer insulating layer 140. The source electrode 123 and the drain electrode 124 may be formed as a single layer or multiple layers including any one of, for example, molybdenum (Mo), aluminum (Al), chromium (Cr), gold (Au), titanium (Ti), nickel (Ni), neodymium (Nd), and copper (Cu), or alloys thereof.

The passivation layer 150 for insulating the thin film transistor 120 may be formed on the source electrode 123 and the drain electrode 124. The passivation layer 150 may be formed as an inorganic film such as a silicon nitride layer, a silicon oxynitride layer, a silicon oxide layer, a titanium oxide layer, or an aluminum oxide layer.

The planarization layer 160 for planarizing a step due to the thin film transistor 120 may be formed on the passivation layer 150. The planarization layer 160 may be formed as an organic film including, for example, an acrylic resin, an epoxy resin, a phenolic resin, a polyamide resin, a polyimide resin, or the like.

The light emitting element layer EML is formed on the thin film transistor layer TFTL. The light emitting element layer EML includes light emitting elements 170 and a pixel defining layer 180.

The light emitting elements 170 and the pixel defining layer 180 are formed on the planarization layer 160. Each of the light emitting elements 170 may include a first electrode 171 (e.g., pixel electrode), an organic light emitting layer 172, and a second electrode 173.

The first electrode 171 may be formed on the planarization layer 160. The first electrode 171 is connected to the source electrode 123 of the thin film transistor 120 through a contact hole penetrating through the passivation layer 150 and the planarization layer 160.

In a top emission structure in which light is emitted toward the second electrode 173 based on the organic light emitting layer 172, the first electrode 171 may be made of a metal material having a high reflectivity, such as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy is an alloy of silver (Ag), palladium (Pd), and copper (Cu).

In a bottom emission structure in which light is emitted toward the first electrode 171 based on the organic light emitting layer 172, the first electrode 171 may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). In this case, when the first electrode 171 includes the semi-transmissive conductive material, light emission efficiency may be increased by a micro cavity.

The pixel defining layer 180 may be formed to partition the first electrodes 171 on the planarization layer 160 to serve as a pixel defining layer defining the sub-pixels RP, GP, and BP. The pixel defining layer 180 may be formed to cover an edge of the first electrode 171. For example, the pixel defining layer 180 may expose a portion of the first electrode 171. The pixel defining layer 180 may be formed as an organic film including, for example, an acrylic resin, an epoxy resin, a phenolic resin, a polyamide resin, a polyimide resin, or the like.

Each of the sub-pixels RP, GP, and BP refers to an area in which the first electrode 171, the organic light emitting layer 172, and the second electrode 173 are sequentially stacked and holes from the first electrode 171 and electrons from the second electrode 173 are combined with each other in the organic light emitting layer 172 to emit light. Each of the sub-pixels RP, GP, and BP may include the light emitting element 170.

The organic light emitting layer 172 is formed on the first electrode 171 and the pixel defining layer 180. The organic light emitting layer 172 may include an organic material to emit light of a predetermined color. For example, the organic light emitting layer 172 may include a hole transporting layer, an organic material layer, and an electron transporting layer. In this case, the organic light emitting layer 172 of the first sub-pixel RP may emit light of a first color, and the organic light emitting layer 172 of the second sub-pixel GP may emit light of a second color. In addition, the organic light emitting layer 172 of the third sub-pixel BP may emit light of a third color. The first color may be red, the second color may be green, and the third color may be blue, but the present invention is not limited thereto.

In addition, the organic light emitting layer 172 of each of the sub-pixels RP, GP, and BP may emit white light, and in this case, the first sub-pixel RP may overlap a color filter layer of the first color, the second sub-pixel GP may overlap a color filter layer of the second color, and the third sub-pixel BP may overlap a color filter layer of the third color.

The second electrode 173 is formed on the organic light emitting layer 172. The second electrode 173 may be formed to cover the organic light emitting layer 172. The second electrode 173 may be a common layer formed in common in the sub-pixels RP, GP, and BP. A capping layer may be formed on the second electrode 173.

In the top emission structure, the second electrode 173 may include, for example, a transparent conductive material (TCO) such as ITO or IZO capable of transmitting light therethrough or a semi-transmissive conductive material such as magnesium (Mg), silver (Ag), or an alloy of magnesium (Mg) and silver (Ag). When the second electrode 173 includes the semi-transmissive conductive material, light emission efficiency may be increased by a micro cavity.

In the bottom emission structure, the second electrode 173 may be made of a metal material having high reflectivity, such as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy is an alloy of silver (Ag), palladium (Pd), and copper (Cu).

The thin film encapsulation layer TFEL is formed on the light emitting element layer EML. The thin film encapsulation layer TFEL includes an encapsulation layer 190.

The encapsulation layer 190 is disposed on the second electrode 173. The encapsulation layer 190 may include at least one inorganic film to prevent oxygen or moisture from penetrating into the organic light emitting layer 172 and the second electrode 173. In addition, the encapsulation layer 190 may include at least one organic film to protect the light emitting element layer EML from foreign substances such as dust. For example, the encapsulation layer 190 may include a first inorganic film disposed on the second electrode 173, an organic film disposed on the first inorganic film, and a second inorganic film disposed on the organic film. The first inorganic film and the second inorganic film may be formed as, for example, a silicon nitride layer, a silicon oxynitride layer, a silicon oxide layer, a titanium oxide layer, or an aluminum oxide layer, but the present invention is not limited thereto. The organic film may be made of an acrylic resin, an epoxy resin, a phenolic resin, a polyamide resin, a polyimide resin, or the like, but the present invention is not limited thereto.

A second buffer layer BF2 is formed on the thin film encapsulation layer TFEL. The second buffer layer BF2 may include a plurality of inorganic films that are alternately stacked on each other. For example, the second buffer layer BF2 may be formed as multiple films in which one or more inorganic films of a silicon nitride layer, a silicon oxynitride layer, a silicon oxide layer, a titanium oxide layer, and an aluminum oxide layer are alternately stacked on each other. The second buffer layer BF2 may be omitted.

The touch sensing layer TSL is formed on the second buffer layer BF2. The touch sensing layer TSL may include the driving electrodes TE, the sensing electrodes RE, the connection electrodes BE, the first driving lines TL1, the second driving lines TL2, the sensing lines RL, the guard lines GL1, GL2, GL3, GL4, and GL5, and the ground lines GRL1, GRL2, and GRL3, as illustrated in FIG. 5. In FIG. 7, for convenience of explanation, the driving electrode TE, the sensing electrode RE, and the connection electrode BE of the touch sensing layer TSL have been illustrated.

The connection electrode BE may be disposed on the second buffer layer BF2. The connection electrode BE may be formed as a single layer or multiple layers including, for example, any one of molybdenum (Mo), aluminum (Al), chromium (Cr), gold (Au), titanium (Ti), nickel (Ni), neodymium (Nd), and copper (Cu), or alloys thereof.

A first touch insulating film TINS1 is disposed on the connection electrode BE and may include an opening exposing a portion of the connection electrode BE. The first touch insulating film TINS1 may be formed as an inorganic film such as a silicon nitride layer, a silicon oxide layer, a silicon oxynitride layer, a titanium oxide layer, or an aluminum oxide layer. For example, the first touch insulating film TINS1 may be formed as an organic film made of an acrylic resin, an epoxy resin, a phenolic resin, a polyamide resin, a polyimide resin, or the like.

The driving electrode TE and the sensing electrode RE may be disposed on the first touch insulating film TINS1. In addition, the first driving lines TL1, the second driving lines TL2, the sensing lines RL, the guard lines GL1, GL2, GL3, GL4, and GL5, and the ground lines GRL1, GRL2, and GRL3 as well as the driving electrode TE and the sensing electrode RE may be disposed on the first touch insulating film TINS1. For example, the driving electrodes TE, the sensing electrodes RE, the first driving lines TL1, the second driving lines TL2, the sensing lines RL, the guard lines GL1, GL2, GL3, GL4, and GL5, and the ground lines GRL1, GRL2, and GRL3 excluding the connection electrodes BE may be disposed at the same layer as each other and may be made of the same material as each other. Each of the driving electrodes TE, the sensing electrodes RE, the first driving lines TL1, the second driving lines TL2, the sensing lines RL, the guard lines GL1, GL2, GL3, GL4, and GL5, and the ground lines GRL1, GRL2, and GRL3 may be made of, for example, a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO, but an embodiment of the present invention is not limited thereto. The connection electrodes BE illustrated in FIG. 5 may be formed on the first touch insulating film TINS1. Each of the connection electrodes BE may be connected to the driving electrodes TE through a touch contact hole TCNT penetrating through the first touch insulating film TINS1. The driving electrodes TE disposed in the second direction (Y-axis direction) may be electrically connected to each other by the connection electrodes BE. The connection electrodes BE may be made of, for example, a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO, but the present invention is not limited thereto.

A second touch insulating film TINS2 is formed on the driving electrode TE and the sensing electrode RE. The second touch insulating film TINS2 may serve to planarize a step formed due to the driving electrode TE, the sensing electrode RE, and the connection electrode BE. For example, the second touch insulating film TINS2 may be formed as an organic film made of an acrylic resin, an epoxy resin, a phenolic resin, a polyamide resin, a polyimide resin, or the like.

The window WM is disposed on the touch sensing layer TSL.

As described above, the plurality of grooves re arranged in the first direction (X-axis direction) and extending in the second direction (Y-axis direction) that is substantially perpendicular to the first direction (X-axis direction) may be provided in the lower surface of the window WM. The viewing angle control member LCU may be disposed in each of the plurality of grooves re. Accordingly, a plurality of viewing angle control members LCU are disposed at regular intervals in the first direction (X-axis direction). A width W1 of each of the plurality of grooves re may be in the range of about 2 μm to about 4 μm, and is, for example, approximately 3 μm.

An angle formed by an inner sidewall of each of the plurality of grooves re may be about 90° with respect to an upper surface of the second touch insulating layer TINS2. Accordingly, loss of light traveling in an upward direction (Z-axis direction) of the display panel 100 among light of the light emitting element layer EML may be easily prevented.

As a height d1 of the viewing angle control member LCU increases, a ratio of light absorbed by light absorbing walls LCW of the viewing angle control members LCU to be described later to the light of the sub-pixels RP, GP, and BP may increase. Therefore, to increase light absorption efficiency of side light of the sub-pixels RP, GP, and BP, the height d1 of the viewing angle control member LCU may be in the range of about 5 μm to about 10 μm, and is, for example, approximately 6 μm. The height of the viewing angle control member LCU refers to a distance from a lower surface of the viewing angle control member LCU to an upper surface of the viewing angle control member LCU.

In addition, as the number of viewing angle control members LCU increases, the light absorption efficiency of the side light of the sub-pixels RP, GP, and BP may increase. However, as the number of viewing angle control members LCU on the sub-pixels RP, GP, and BP increases, a ratio of the light traveling in the upward direction (Z-axis direction) of the sub-pixels RP, GP, and BP may decrease by a thickness of the light absorbing walls LCW of the viewing angle control members LCU. Accordingly, a spaced distance d2 between the viewing angle control members LCU may be in the range of about 8 μm to about 10 μm. The spaced distance d2 between the viewing angle control members LCU and the height d1 of the viewing angle control member LCU may be the same dimension, but the present invention is not limited thereto. Here, the spaced distance between the viewing angle control members LCU may be a distance from the central axis of a first viewing angle control member LCU to the central axis of a second viewing angle control member LCU adjacent to the first viewing angle control member LCU.

Upper and lower surfaces of the viewing angle control member LCU may have a light transmission property.

The viewing angle control member LCU may include the light absorbing wall LCW and a filler LCF.

The light absorbing walls LCW are disposed on sidewalls of the grooves re of a lower surface WMB of the window WM. Accordingly, the light absorbing walls LCW may be formed based on a shape of the grooves re provided in the lower surface WMB of the window, and, a traveling direction of light output through a display surface may be controlled. The light absorbing wall LCW and the traveling direction of the light will be described later with reference to FIG. 9.

A width W2 of the light absorbing wall LCW on one surface of the window WM may be in the range of about 0.15 μm to about 0.5 μm, and may be, for example, about 0.3 μm. The light absorbing wall LCW may be formed to become thinner toward an upper portion of the window WM. The light absorbing wall LCW may be formed in a single layer structure of, for example, CuMgAlOₓ, but the present invention is not limited thereto, and may be made of any material having a low reflection light absorption function and having adhesiveness to a sidewall of the window WM. CuMgAlOₓ has a low reflectivity and a high light absorption function and does not require a separate adhesive because it is adhesively formed on the sidewall of the groove re of the window WM. Accordingly, a process may be simplified.

In addition, the viewing angle control member LCU may further include the filler LCF. In an embodiment of the present invention, the light absorbing walls LCW may be disposed on inner walls of the plurality of grooves re, and the plurality of grooves re may be filled with the fillers LCF. For example, each of the fillers LCF may be disposed between a pair of light absorbing walls LCW that are in each of the grooves re. The filler LCF becomes wider towards the center of the window WM. The filler LCF may be formed of, for example, a transparent oxide film, for example, silica (SiO₂) and a siloxane-based material. However, the present inventive concept is not limited thereto. For example, instead of the filler LCF, air may be provided between the light absorbing walls LCW.

The viewing angle control members LCU may be disposed on the touch sensing layer TSL. At least some of the viewing angle control members LCU may overlap the touch electrodes TE and RE in a third direction (Z-axis direction), for example, the thickness direction.

A protective layer PRL may be disposed on the lower surface WMB of the window WM in an area where the viewing angle control member LCU is not disposed. For example, the protective layer PRL may be disposed between the viewing angle control members LCU.

The protective layer PRL may be disposed between the window WM and the touch sensing layer TSL.

The protective layer PRL may be made of, for example, transparent IZO or IGZO. The protective layer PRL may be omitted.

FIG. 9 is a partially enlarged cross-sectional view of the display panel illustrating the travel of light output from the organic light emitting layer of FIG. 7.

Referring to FIG. 9, light output from the organic light emitting layer 172 may be output along the third direction (Z-axis direction). Hereinafter, the light output from the organic light emitting layer 172 will be referred to as output light. Such output light may be output in various directions rather than being output in a direction parallel to the third direction (Z-axis direction).

In addition, hereinafter, light transferred from the organic light emitting layer 172 to the light absorbing wall LCW will be referred to as first light L1. Here, the first light L1 refers to light output from the organic light emitting layer 172 in a state in which it is inclined at a predetermined angle between the third direction (Z-axis direction) and the first direction (X-axis direction). For example, the predetermined angle of the first light L1 may be less than about 90° with respect to an upper surface of the first electrode 171. In addition, light transferred from the organic light emitting layer 172 to the outside after passing between the light absorbing walls LCW will be referred to as second light L2. The second light L2 refers to light output from the light emitting element layer EML in a state in which it is inclined at a predetermined angle between the third direction (Z-axis direction) to the first direction (X-axis direction). For example, the predetermined angle of the second light L2 may be different from the predetermined angle of the first light L1. For example, the predetermined angle of the second light L2 may be about 90° with respect to the upper surface of the first electrode 171.

As described above, the light absorbing walls LCW may be arranged along the first direction (X-axis direction) at regular intervals. When the first light L1 is output from the organic light emitting layer 172, the first light L1 may be transferred to the light absorbing walls LCW. In this case, the first light L1 transferred to the light absorbing walls LCW may be absorbed by the light absorbing walls LCW. For example, the light absorbing walls LCW may block the travel of the first light L1. As a result, the first light L1 is not transferred to the outside through the display surface.

To the contrary, when the second light L2 is output from the organic light emitting layer 172, the second light L2 may pass between the light absorbing walls LCW. For example, the second light L2 may be transferred to the outside through the display surface.

As described above, a traveling direction of the light output through the display surface of the display device 10 may become substantially constant by the light absorbing walls LCW. For example, an image displayed through the display surface might not be projected from other directions that do not face the display surface.

As an example, a display device may be mounted inside a vehicle. In this case, the display device may be disposed inside the vehicle so that a display surface thereof is viewed by a user. In a conventional case, the light output from the organic light emitting layer 172 is output in various directions through the display surface, and accordingly, an image is projected on a windshield of the vehicle. According to an embodiment of the present invention, the light output from the organic light emitting layer 172 may be output through the display surface in a substantially constant direction by the viewing angle control members LCU. As a result, the image may be prevented from being projected on the windshield of the vehicle.

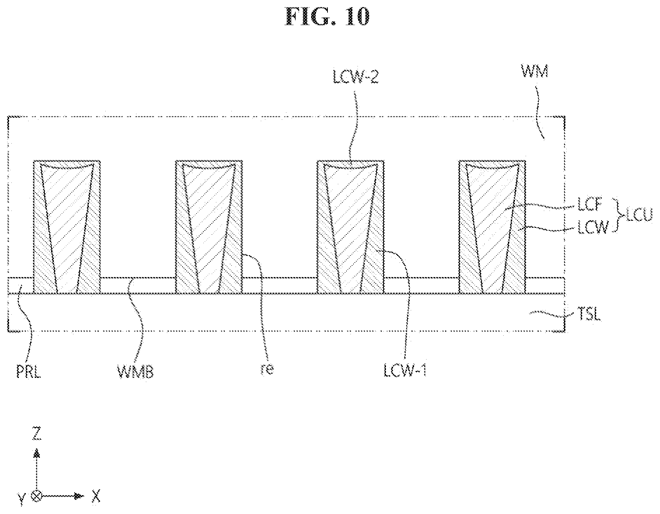

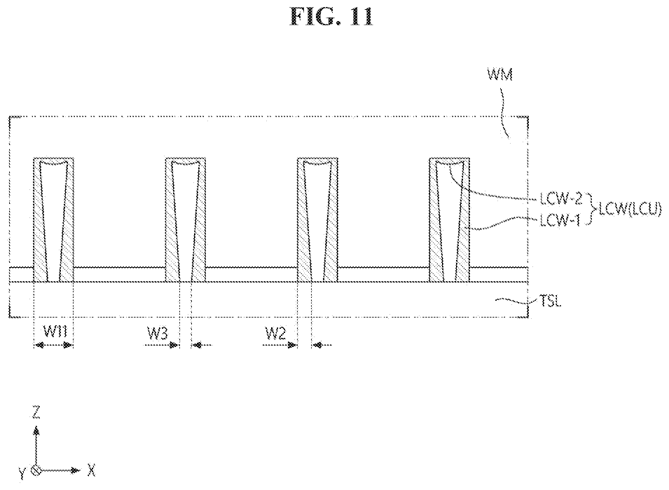

FIGS. 10 and 11 are enlarged views of area B of FIG. 7 according to some embodiments of the present invention.

A window WM illustrated in FIG. 10 may be substantially the same as the window WM illustrated in FIG. 8 except for a configuration of the light absorbing wall LCW. Accordingly, a description of the other components that may be redundant may be omitted.

Referring to FIG. 10, the light absorbing wall LCW may include a first light absorbing wall LCW-1, which is formed on a side surface of the groove re, and a second light absorbing wall LCW-2, which is formed on a bottom surface of the groove re. A thickness of the second light absorbing wall LCW-2 is smaller than a thickness of the first light absorbing wall LCW-1. Accordingly, the second light absorbing wall LCW-2 might not completely absorb light, and light may pass through the second light absorbing wall LCW-2. However, the second light absorbing wall LCW-2 formed on the bottom surface of the groove re does not need to be removed during a process of the light absorbing wall LCW, which simplifies the process.

A window WM illustrated in FIG. 11 may be substantially the same as the window WM illustrated in FIG. 10 except that the width W1 of a viewing angle control member LCU becomes small and the filter of the viewing angle control member LCU is omitted. Accordingly, a description of the other components that may be redundant will be omitted.

Only configurations of the light absorbing wall LCW and the filler LCF are changed, and the other components may be substantially the same as corresponding components previously described, unless indicated otherwise. Accordingly, a description of the other components will be omitted to prevent redundant descriptions.

Referring to FIG. 11, a width W11 of the viewing angle control member LCU may be the same as a width of the groove re of the window WM and may be about 1 μm to about 2 μm. An opening W3 of the groove re of the window WM may become very narrow by a width W2 of the light absorbing wall LCW of the viewing angle control member LCU. In this case, the filler in the groove re of the window WM may be omitted.

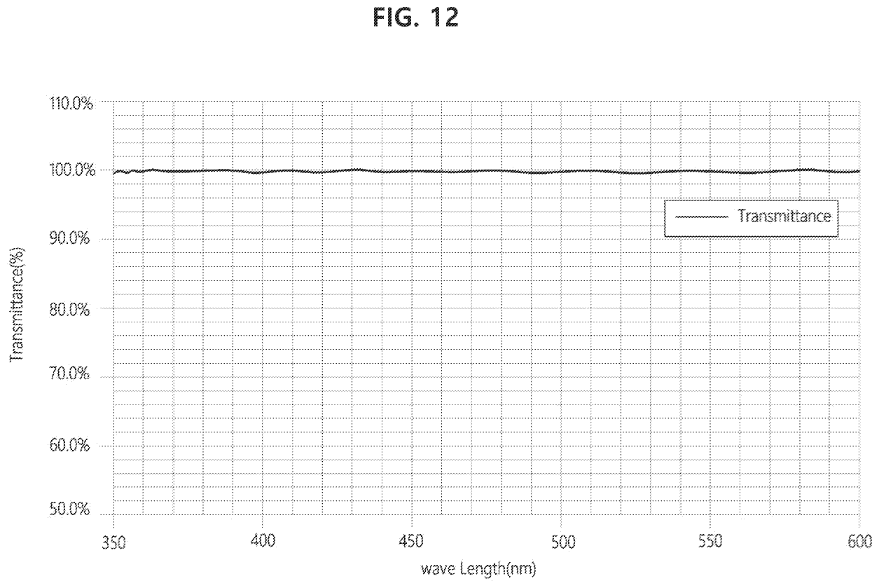

FIG. 12 is a graph for describing transmittance characteristics of silica (SiO₂) and a siloxane-based material with respect to a light wavelength.

Referring to FIG. 12, it may be confirmed that transmittance of silica (SiO₂) and a siloxane based material is almost 100% with respect to all wavelengths of visible light. Accordingly, when an area except for the light absorbing wall LCW of the groove re of the window WM of FIG. 8 is filled with the filler LCF made of transparent silica (SiO₂) and siloxane-based material, light transmittance close to 100% may be expected with respect to all wavelengths of visible light.

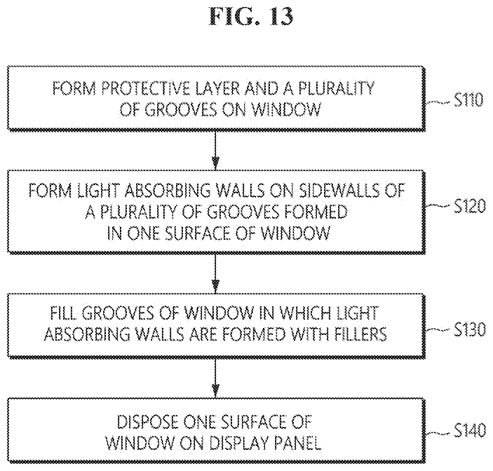

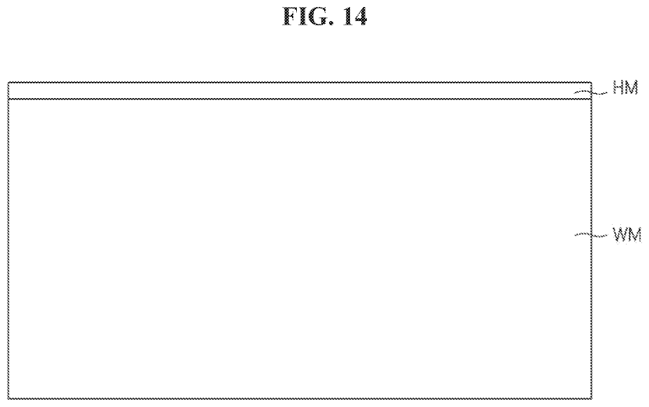

FIG. 13 is a flowchart for describing a method for manufacturing a window according to an embodiment of the present invention. FIGS. 14 to 18 are cross-sectional views for describing the method for manufacturing a window according to an embodiment of the present invention.

Referring to FIGS. 14 to 16, the protective layer PRL and the plurality of grooves re are formed on the window WM (S110 in FIG. 13).

Referring to FIG. 14, a hard mask HM is formed on the window WM. The window WM may be, for example, a glass substrate or a plastic substrate having a light transmission property. For example, when the window WM is the plastic substrate, the window WM may be made of a material such as polyimide (PI), polyethylene terephthalate (PET), polyethylene naphthalate (PEN), polycarbonate (PC), polyethersulfone (PES), polyarylate (PAR), polysulfone (PSF), and cyclic-olefin copolymer (COC).

The hard mask may be a transparent oxide thin film made of, for example, IZO or IGZO.

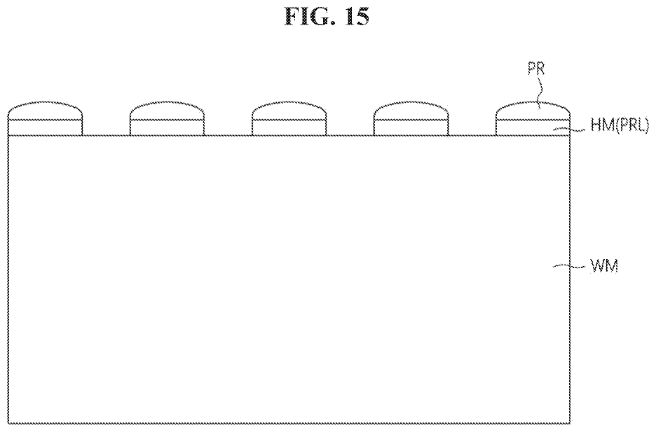

Referring to FIG. 15, the hard mask HM formed on the window WM is patterned using a photoresist mask PR. The patterned hard mask is a protective layer PRL, and may remain without being removed in a subsequent process.

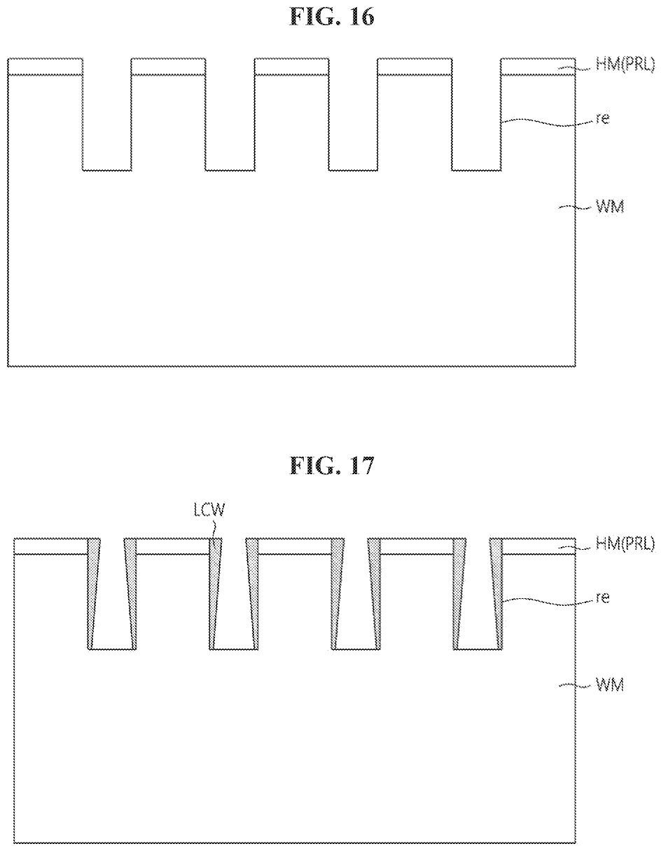

Referring to FIG. 16, grooves re may be formed in the window WM by forming a trench in the window WM by etching with the patterned hard mask HM.

A plurality of grooves re formed using the hard mask HM may be formed at equal intervals and the same depth. The plurality of grooves re may be formed in the range of about 20% or less of a total area of the window WM, but the present invention is not limited thereto. A depth of the groove re may be in the range of about 10% to about 55% of a thickness of the window WM, but the present invention is not limited thereto.

Next, referring to FIG. 17, the light absorbing walls LCW are formed on sidewalls of the plurality of grooves re that are formed in one surface of the window WM (S120 in FIG. 13).

For example, CuMgAl is deposited on one surface of the window WM, and the light absorbing walls LCW are formed on side surfaces of the grooves re by anisotropic etching.

In the anisotropic etching, a great voltage difference is formed in the third direction (Z-axis direction) without a separate mask, and CuMgAl is etched by an etching material. In this case, the etching material may etch light absorbing layers made of CuMgAl while moving in the third direction (Z-axis direction), that is, moving from an upper portion to a lower portion, by voltage control.

The etching material is a material that etches CuMgAl but might not etch the protective layer PRL and the window WM.

For this reason, as illustrated in FIG. 17, a CuMgAl material disposed on a horizontal plane defined by the first direction (X-axis direction) and the second direction (Y-axis direction) and a CuMgAl material disposed at lower portions re-b of the grooves, that is, the light absorbing layers, are removed, while a CuMgAl material disposed on a vertical plane defined by the third direction (Z-axis direction) might not be removed.

CuMgAl has excellent adhesion properties, and, particularly, has excellent adhesion to glass. Accordingly, when the light absorbing walls LCW made of CuMgAl is formed in the window WM made of a glass material, a separate adhesive layer or adhesive is not required.

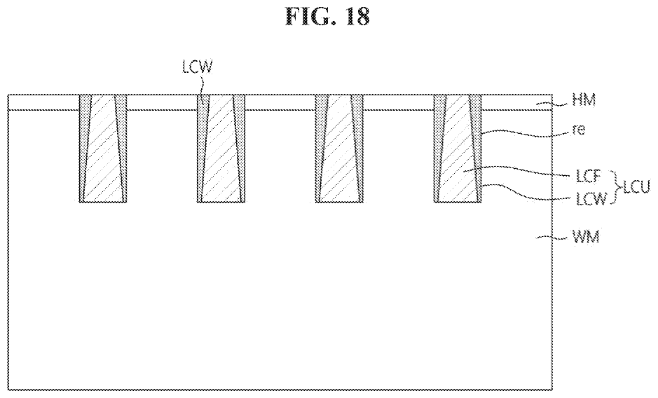

Next, referring to FIG. 18, the fillers LCF are formed inside the grooves re in which the light absorbing walls LCW are formed (S130 in FIG. 13). The filler LCF may be formed of silica (SiO₂) and a siloxane-based material that are transparent. Since a single light absorbing wall LCW made of CuMgAl is formed, a reflection problem of a metal itself may be prevented as compared with a plurality of light absorbing sides including a conventional Ti metal.

Thereafter, CuMgAl is converted into CuMgAlOₓ by performing oxidation heat treatment on the light absorbing walls LCW. In this case, an oxidation heat treatment temperature may be about 250°, but the present invention is not limited thereto.

Next, one surface of the window WM may be disposed on the display panel (S140 in FIG. 13).

Here, the display panel has the same configuration as the display panel described in FIG. 7, and a detailed description thereof will thus be omitted.

In an example, oxidation heat treatment may be performed on the light absorbing walls LCW before the fillers LCF are filled.

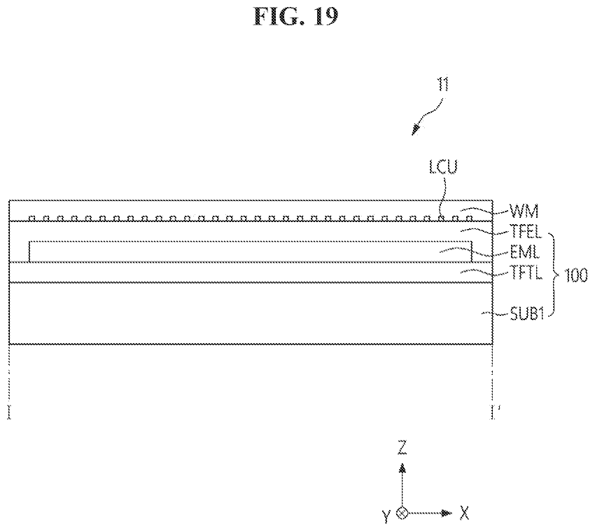

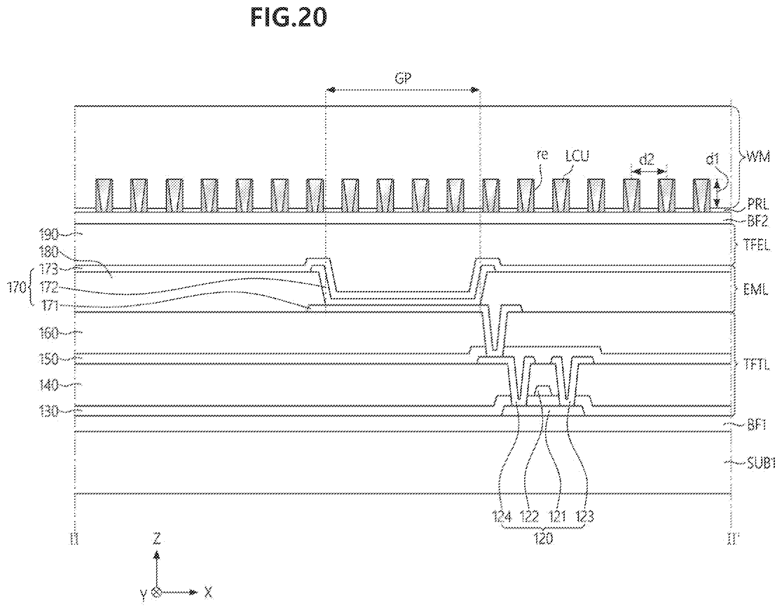

FIG. 19 is a cross-sectional view illustrating an example taken along line I-I′ of FIG. 2 according to an embodiment of the present invention, and FIG. 20 is a cross-sectional view illustrating an example taken along line II-II′ of FIG. 6 according to an embodiment of the present invention.

A display device according to an embodiment of the present invention illustrated in FIGS. 19 and 20 is different from the display device illustrated in FIGS. 3 and 7 in that the touch sensing layer TSL is omitted.

Referring to FIGS. 19 and 20, a display device 11 may include a substrate SUB1, a thin film transistor layer TFTL disposed on the substrate SUB1, a light emitting element layer EML, a thin film encapsulation layer TFEL, and a window WM. Viewing angle control members LCU may be disposed in grooves re formed in one surface of the window WM.

For example, the viewing angle control members LCU may be disposed on the thin film encapsulation layer TFEL. For example, the viewing angle control members LCU may be formed on the second buffer layer BF2 that is formed on the thin film encapsulation layer TFEL.

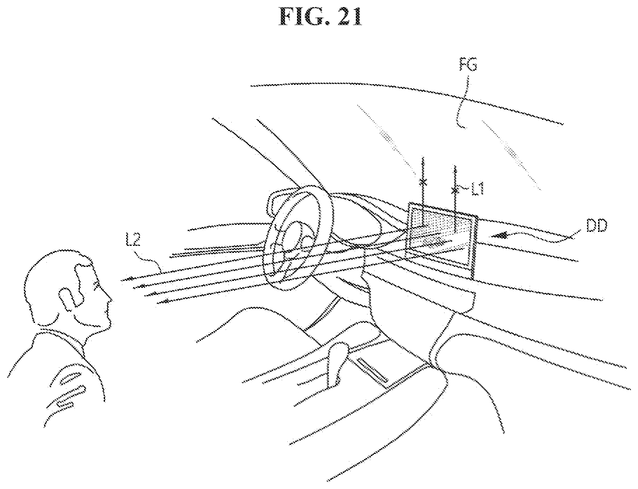

FIG. 21 is a view illustrating an example to which a display device according to an embodiment of the present invention is applied.

As an example, FIG. 21 illustrates that a display device according to an embodiment of the present invention is mounted inside a vehicle. Hereinafter, it will be described that a display device DD is mounted inside the vehicle so as to be adjacent to a driver's seat of the vehicle.

According to an embodiment of the present invention, the display device DD may be a flat display device. As an example, the display device DD may be a navigation device displaying traffic information and the like. A display surface of the display device DD may be disposed inside the vehicle so as to face a user's sight line. For example, the display surface of the display device DD may be a surface parallel to the second direction (Y-axis direction) and the third direction (Z-axis direction), and may face the user's sight line of in the first direction (X-axis direction).

As described above, light may be output from the display surface of the display device DD based on the first direction (X-axis direction) by a light blocking member. For example, light is not output in the third direction (Z-axis direction) from the display surface of the display device DD, and accordingly, an image might not be projected on a windshield FG.

The display device according to an embodiment of the present invention may have a reduced entire thickness and provide a privacy function by forming the viewing angle control members, which absorb light traveling in a lateral direction of the light emitting element layer, in the window.

While the present invention has been described with reference to the embodiments thereof, it will be understood by those of ordinary skill in the art that various changes in form and detail may be made thereto without departing from the spirit and scope of the present invention.

What is claimed is:

1. A display device comprising:
a display panel including a display area and a non-display area;
a window disposed above the display panel and having a plurality of grooves that are formed on one surface of window facing the display panel; and
viewing angle control members formed inside the plurality of grooves,
wherein the viewing angle control members include light absorbing walls formed on sidewalls of the plurality of grooves and formed to become thinner as upper surfaces of the plurality of grooves are approached.

2. The display device of claim 1, wherein the light absorbing wall includes CuMgAlOₓ.

3. The display device of claim 1, wherein the viewing angle control members further includes fillers filled in inner portions of the grooves and are at least partially surrounded by the light absorbing walls, and
the fillers are formed to become wider as the upper surfaces of the plurality of grooves are approached.

4. The display device of claim 3, wherein the filler is made of silica (SiO₂) and a siloxane-based material.

5. The display device of claim 1, wherein a protective layer is disposed on one surface of the window and is disposed between the viewing angle control members.

6. The display device of claim 5, wherein the protective layer includes a transparent oxide film.

7. The display device of claim 1, wherein each of the light absorbing walls includes a first light absorbing wall and a second light absorbing wall, wherein the first light absorbing walls is formed on the sidewalls of the plurality of grooves, and the second light absorbing walls are formed on the upper surfaces of the plurality of grooves, and
the second light absorbing walls are formed to be thinner than the first light absorbing walls.

8. The display device of claim 1, wherein the viewing angle control members includes fillers contacting the light absorbing walls.

9. The display device of claim 1, further comprising a touch sensing layer disposed between the display panel and the window,
wherein the viewing angle control members are disposed to face the touch sensing layer.

10. The display device of claim 9, wherein the touch sensing layer includes touch electrodes, and
at least some of the viewing angle control members overlap the touch electrodes.

11. The display device of claim 1, wherein the display panel includes:
a substrate;
a light emitting element layer disposed on the substrate and including pixels including a pixel electrode, a light emitting layer, and a common electrode, and a pixel defining layer disposed on the pixel electrode; and
a thin film encapsulation layer disposed on the light emitting element layer.

12. The display device of claim 11, wherein the viewing angle control members are disposed to face the thin film encapsulation layer.

13. A method for manufacturing a display device, comprising:
forming a plurality of grooves in a first surface of a window by using a hard mask and a photoresist mask;
forming light absorbing walls on side surfaces of the plurality of grooves;
filling inner portions of the grooves with fillers such that the fillers are at least partially surrounded by the light absorbing walls; and
disposing the first surface of the window on a display panel,
wherein the light absorbing walls are formed to become thinner as upper portions of the window are approached.

14. The method for manufacturing a display device of claim 13, further comprising performing oxidation heat treatment on the light absorbing walls.

15. The method for manufacturing a display device of claim 13, wherein the hard mask includes a transparent oxide film.

16. The method for manufacturing a display device of claim 13, wherein in the forming of the light absorbing walls,
CuMgAl is deposited on one surface of the window in which the grooves are formed, and is anisotropically etched.

17. The method for manufacturing a display device of claim 16, wherein the filler includes silica (SiO₂) and a siloxane-based material.

18. The method for manufacturing a display device of claim 17, wherein the fillers are formed to become wider as the upper portions of the window are approached.

19. The method for manufacturing a display device of claim 13, wherein the display panel includes:
a substrate;
a light emitting element layer disposed on the substrate and including pixels including a pixel electrode, a light emitting layer, and a common electrode, and a pixel defining layer disposed on the pixel electrode; and
a thin film encapsulation layer disposed on the light emitting element layer.

20. The method for manufacturing a display device of claim 13, further comprising disposing a touch sensing layer on the display panel.
